(19) United States
(12) Patent Application Publication
(10) Pub. No.: US 2005/0161725 A1
(43) Pub. Date: Jul. 28, 2005

(54) Semiconductor component comprising an integrated latticed capacitance structure

(76) Inventor: Nicola Da Dalt, Villach (AT)

Correspondence Address: Jasper W Dockrey;Brinks Hofer Gilson & Lione, P O Box 10395, Chicago, IL, 60610, US

(21) Appl. No.: 10/511,855

(22) PCT Filed: Apr. 9, 2003
(86) PCT No.: PCT/DE03/01171

(30) Foreign Application Priority Data
Apr. 19, 2002 (DE) 102175659

(51) Int. Cl. H01L 27/108

(52) U.S. Cl. 257/306

(57) ABSTRACT

An insulating layer which is produced on a semiconductor substrate has a capacitance structure produced in it. The capacitance structure has at least one first substructure which has a metal latticed region and electrically conductive regions which are arranged in the cutouts in the metal latticed region, the metal latticed region are electrically connected to a first connecting line, and the electrically conductive regions are electrically connected to a second connecting line.

The present invention relates to a semiconductor component having a semiconductor substrate on which an insulating layer is produced, the insulating layer having a capacitance structure produced in it.

Most analog circuit parts of hybrid digital/analog circuits require capacitors having a high capacitance value, a high level of linearity and high quality. In order to keep the costs for fabricating the component as low as possible, it is necessary for the fabrication of the capacitance structures to require as few process steps as possible. In addition, the progressive miniaturization of the components and integrated circuits also entails the demand for as little area requirement as possible for the capacitance structure.

A capacitance structure which is known in the prior art is known from patent specification DE 198 50 915 C1. A structure which is in the form of a “sandwich capacitance” has two conductive foils which have been applied to a semiconductor substrate and are isolated from one another by a dielectric layer. The top foil resting on the dielectric layer is connected to at least one of the two connecting conductors for the capacitance via at least one conductive air bridge. Parasitic inductances in the capacitance are largely compensated for by virtue of the two connecting conductors being connected to one another by at least one highly resistive line which bridges the capacitance.

A further design for a capacitance structure is known from patent specification U.S. Pat. No. 5,208,725. On a semiconductor substrate, a plurality of first lines in strip form are arranged parallel to one another. Isolated by a dielectric layer, a plurality of second lines are arranged congruently on these first lines. By virtue of vertically and laterally adjacent lines being at different potentials, both capacitances between lines situated above one another and capacitances between adjacent lines in one plane are produced. A substantial drawback of this structure is that a minimal shift in the metal lines arranged above one another reduces the vertical capacitance components to a relatively great extent and reduces the share of the useful capacitance.

A further capacitance structure is known from Aparicio, R. and Hajimiri, A.: Capacity Limits and Matching Properties of Lateral Flux Integrated Capacitors; IEEE Custom Integrated Circuits Conference, San Diego, May 6-9, 2001. Vertically arranged bar structures are arranged symmetrically with respect to one another. Each of the bars is constructed from metal regions and via regions, which are arranged alternately on one another. The spots of metal on a bar are at a common potential. Spots of metal on adjacent bars are at different potentials. The via regions respectively make contact with two adjacent metal regions on a bar. Fabricating this structure is very complex—many masking steps are required—and the capacitance density is limited by the minimum size of the metal regions in the bars. The size of these metal regions is much larger than the size of the via regions in the bars, however, which is down to the fact that the demands placed on masks for fabricating the metal regions are different than those on masks used to fabricate the via regions. A drawback of these capacitance structures is that the parasitic capacitance with respect to the substrate is relatively large and is essentially the same size regardless of the orientation of the capacitance structure—original orientation or vertical rotation through 180°—with respect to the substrate.

Patent specification U.S. Pat. No. 5,583,359 has disclosed a capacitance structure for an integrated circuit. In this case, a plurality of metal plates which form the electrodes of a stack capacitor are arranged above one another, isolated by dielectric layers. An edge region of each metal plate has a cutout which contains, in the plane of the metal plate, a metal line (in the form of a strip) insulated from the respective plate. Contact with the metal lines is respectively made from both sides using via connections, as a result of which firstly all plates in odd-numbered positions and secondly all plates in even-numbered positions in the stack are electrically connected to one another. As a result of the plates in even-numbered positions being connected to a first connecting line and the plates in odd-numbered positions being connected to a second connecting line, adjacent plates are at different potentials and form respective pairs of electrodes in a plate capacitor. The capacitance surface is thus formed essentially by the plate surfaces. In one alternative embodiment, one of the electrodes of the stack capacitor is in the form of a homogeneous metal plate which is surrounded by a frame which is arranged at a distance from the metal plate and is at a different potential than the metal plate. Regardless of their arrangement with respect to the substrate, the capacitance structures shown have a relatively high parasitic capacitance. In a series of novel applications in which capacitance structures are required, it is desirable or necessary to produce capacitance structures in which at least one electrode structure of the capacitance has a relatively low, ideally no, parasitic capacitance relative to the substrate in comparison with the second electrode structure.

It is therefore an object of the present invention to provide a semiconductor component having an integrated capacitance structure where the ratio of useful capacitance to parasitic capacitance can be improved.

This object is achieved by a semiconductor component which has the features of patent claim 1.

A semiconductor component has a semiconductor substrate on which a layer system comprising one or more insulating layers and dielectric layers is arranged. This insulating layer or this insulating layer system has a capacitance structure produced in it.

In line with the invention, the capacitance structure has a first substructure which is produced essentially entirely in a first plane and has two elements. A first element of the substructure is in the form of a latticed region which has a plurality of cohesive, metal frame structures. The latticed region extends essentially parallel to the substrate surface and may be produced in a metallization plane, in particular. The latticed region is electrically connected to a first connecting line. The second element of the first substructure are electrically conductive regions which are arranged in the cutouts in the latticed region. Each electrically conductive region is arranged in one of the cutouts at a distance from the edge regions of this cutout. The electrically conductive regions are electrically connected to a second connecting line.

This permits a capacitance structure having a relatively small parasitic capacitance, which is furthermore relatively simple to fabricate—few mask steps—and requires little space. This means that it is possible to produce even the smallest capacitance structures with relatively high useful capacitance and an improved useful capacitance to parasitic capacitance ratio.

In one advantageous configuration, the electrically conductive regions are in the form of metal plates or in the form of electrically conductive node points, each node point being able to be in the form of one end of a via connection or else a connection connecting two respective via connections. The via connections may be in the form of electrical connections which electrically connect substructures of the capacitance structure or electrically connect a substructure of the capacitance structure and a region of the semiconductor component which is not part of the capacitance structure.

In one preferred embodiment, the capacitance structure has a second substructure which is produced parallel to and at a distance from the first substructure in the insulating layer and is electrically connected to the first substructure. The second substructure has a metal, cohesive latticed region.

This means that it is possible to increase the ratio of useful capacitance to parasitic capacitance in the capacitance structure, with one electrode structure having a minimum parasitic capacitance relative to the substrate in comparison with the second electrode structure.

One advantageous exemplary embodiment is characterized in that the second substructure is of essentially the same design as the first substructure, and the two substructures are arranged vertically offset from one another such that crossing points in the latticed region of the first substructure are arranged vertically above the electrically conductive regions of the second substructure, and the electrically conductive regions of the first substructure are arranged vertically above the crossing points in the latticed region of the second substructure.

Preferably, the two substructures are electrically connected by means of via connections. Provision may be made for each of the vertically aligned pairs comprising
an electrically conductive region and a crossing point to be electrically connected by means of one or more via connections. Depending on the technology used for fabricating the capacitance structure or for the semiconductor component, this may respectively be used to provide a relatively good and secure electrical connection between the individual planes or the substructures.

A further exemplary embodiment is advantageously characterized in that the second substructure has just one metal latticed region which is offset from the first substructure such that the crossing points in the latticed region of the second substructure are arranged vertically below the electrically conductive regions of the first substructure. The electrical connection between the first and second substructures is preferably produced by via connections, with the electrical connection between the electrically conductive regions of the first substructure and the crossing points in the latticed region being formed. This embodiment has a particularly low parasitic capacitance. Particularly as a result of the second substructure closer to the substrate, which is just in the form of a latticed structure, an electrode structure is produced which has a considerably reduced parasitic capacitance relative to the substrate as compared with the other electrode structure of the total capacitance structure.

A further advantageous configuration is characterized by a third substructure of the capacitance structure. The third substructure is in the form of a metal plate and is arranged between the substrate surface and the second substructure. The third substructure may be electrically connected by means of via connections to the electrically conductive regions or to the crossing points in the latticed region of the second substructure.

Further advantageous configurations of the inventive semiconductor component are specified in the subclaims.

A plurality of exemplary embodiments of the inventive semiconductor component are explained in more detail below with reference to schematic drawings, in which:

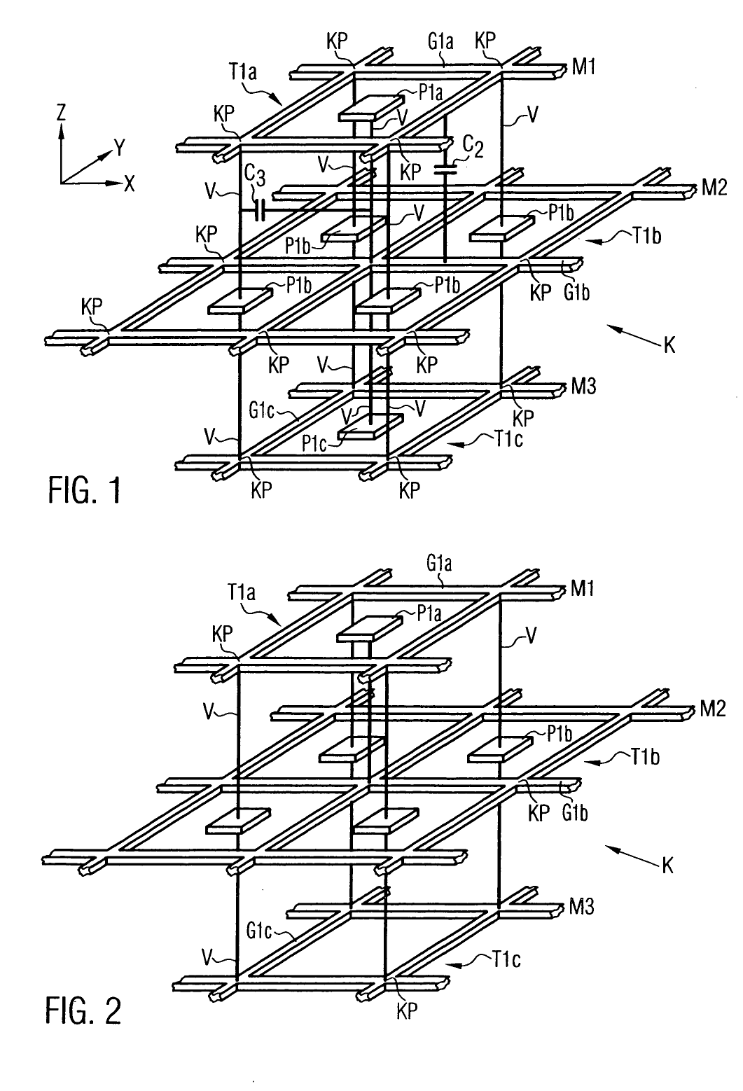

FIG. 1 shows a perspective illustration of a first exemplary embodiment of a semiconductor component based on the invention;

FIG. 2 shows a perspective illustration of a second exemplary embodiment of the semiconductor component based on the invention;

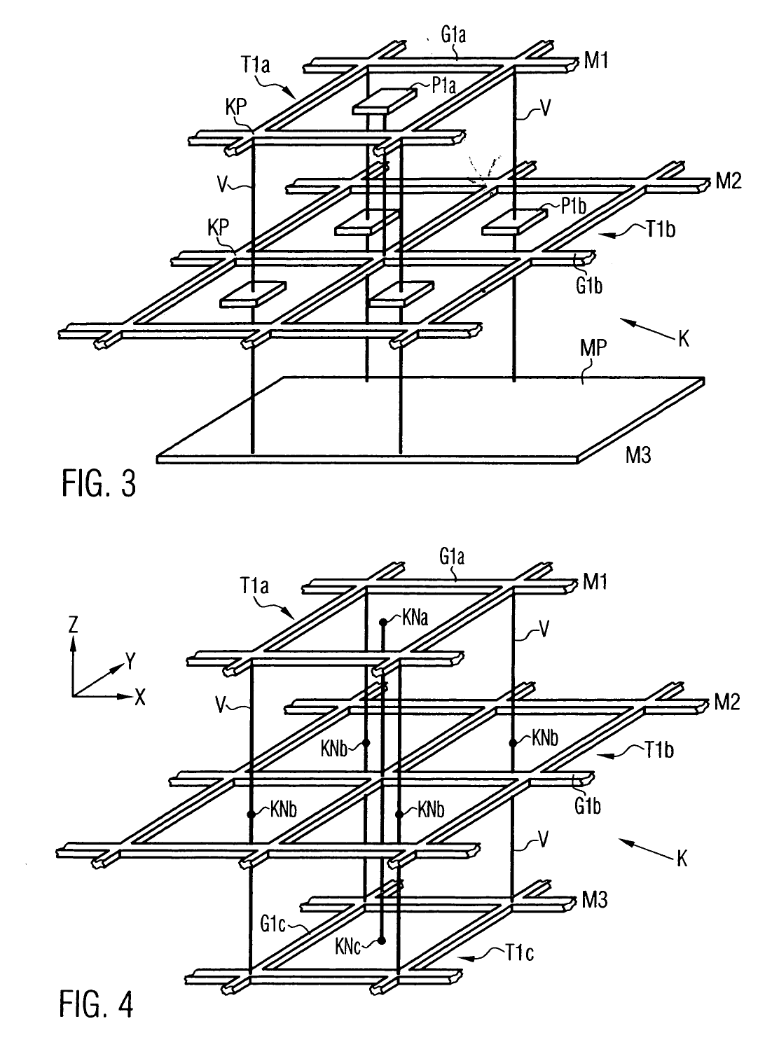

FIG. 3 shows a perspective illustration of a third exemplary embodiment of the semiconductor component based on the invention;

FIG. 4 shows a perspective illustration of a fourth exemplary embodiment of the semiconductor component based on the invention;

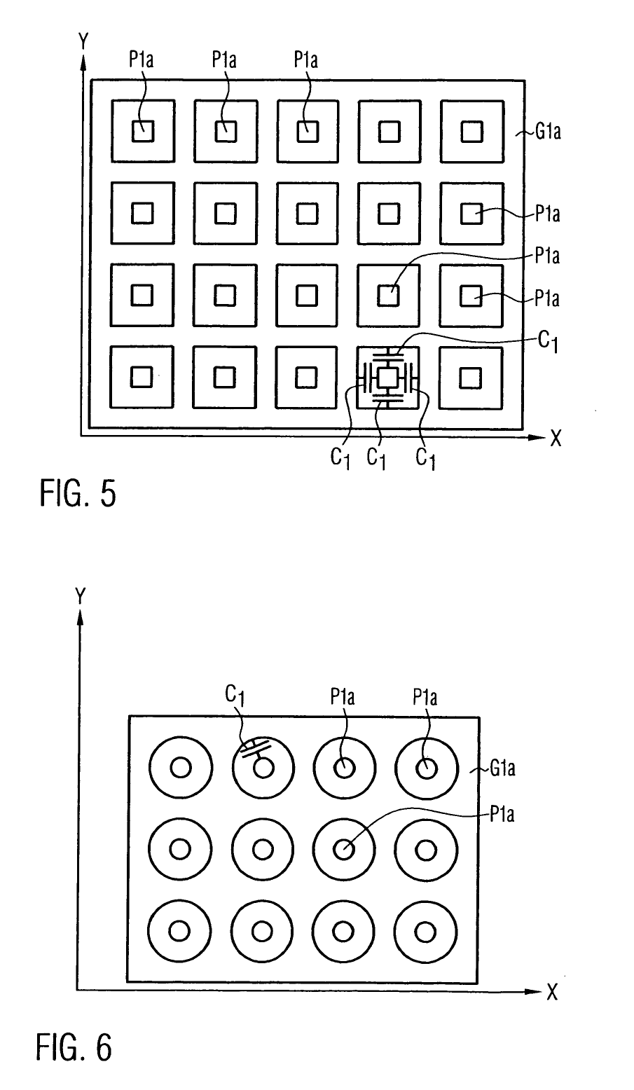

FIG. 5 shows the plan view of a semiconductor component as shown in one of FIGS. 1 to 3; and

FIG. 6 shows the plan view of a further embodiment of the semiconductor component.

In the figures, elements which are the same or have the same function are denoted by the same reference symbols.

A semiconductor component based on the invention (FIG. 1) has a capacitance structure K which is produced in an insulating layer or insulating layer system (not shown). The insulating layer and the capacitance structure K are arranged on a semiconductor substrate (not shown). In the exemplary embodiment, the capacitance structure K has a first substructure T1a. The substructure T1a is produced from a metal latticed region G1a and a plurality of metal plates P1a. Each of the cutouts in the latticed region G1a has a metal plate P1a centrally arranged in it. The metal plates P1a and the latticed region G1a are produced in one metallization plane M1, the latticed region G1a being electrically connected to a first connecting line (not shown) and forming an electrode for the capacitance structure K. The metal plates P1a are electrically connected to a second connecting line (not shown). This forms first useful capacitance components of the capacitance structure in the metallization plane M1. These capacitance components C₁ (shown in FIG. 5) are respectively formed between the surface regions of the latticed region G1a and of a metal plate P1a which are opposite one another in the metallization plane M1.

The capacitance structure K has a second substructure T1b which is produced in line with the first substructure T1a. The substructure T1b is produced in a second metallization plane M2 which is produced parallel to and at a distance from the first metallization plane M1, the two metallization planes being isolated from one another by the insulating layer or by a dielectric layer produced in the insulating layer system. The substructure T1b has a latticed region G1b and metal plates P1b. The second substructure T1b is arranged offset from the first substructure T1a in the x-y plane, specifically such that the metal plates P1b are arranged vertically below the crossing points KP in the latticed region G1a of the first substructure T1a.

Each of the crossing points KP in the latticed region G1a is electrically connected to the metal plate P1b arranged vertically below, and each metal plate P1a is electrically connected to the crossing point KP in the latticed region G1b which is arranged vertically below, by means of via connections V. In the exemplary embodiment, each electrical connection between a crossing point KP and a metal plate is produced using a single via connection V. Provision may also be made for two or more via connections V to be produced between a crossing point KP and a metal plate.

The electrical connection between the first substructure T1a and the second substructure T1b via the via connections V electrically connect the metal plates P1b to the first connecting line and electrically connect the latticed region G1b to the second connecting line. This forms further useful capacitance components. Firstly, further capacitance components C₁ are produced in the x-y plane between the opposing surface regions of the metal plates P1b and the latticed region G1b. Capacitance components C₂ are formed between the latticed regions G1a and G1b at the points at which surface regions of the lattice structures intersect when viewed in the z direction—corresponding to a plan view of FIG. 1. By way of example and by way of representation of all other capacitance components C₂ produced in this manner, a single instance is shown in FIG. 1. Further capacitance components C₃ contributing to the useful capacitance of the capacitance structure K are produced between the via connections V. In this case, the via connections V producing an electrical connection between the metal plates P1a and the crossing points KP in the latticed region G1b are connected to the second connecting line and have a different potential than the via connections V which produce an electrical connection between the crossing points KP in the latticed region G1a and the metal plates P1b. By way of example and by way of representation of all other capacitance components C₃ produced in this manner, a single instance is shown in FIG. 1.

A further substructure T1c of the capacitance structure K is produced in the metallization plane M3. The substructure T1c is likewise produced in line with the first substructure T1a and has a metal latticed region G1c whose cutouts contain metal plates P1c. The substructure T1c is arranged essentially congruently with respect to the substructure T1a. As a result, the crossing points KP in the latticed region G1c of the substructure T1c are arranged vertically below the metal plates P1b, and the metal plates P1c are arranged vertically below the crossing points KP in the latticed region G1b of the substructure T1b. Via connections V produce the electrical connections between the respective crossing points KP and the metal plates P1b and P1c.

This means that the latticed region G1c is electrically connected to the first connecting line, and the metal plates P1c are electrically connected to the second connecting line.

On the basis of the explanations above, capacitance components C₁ are produced between the metal plates P1c and the latticed region G1c in the x-y plane. Capacitance components C₂ are produced between the substructures T1b and T1c in line with those between the substructures T1a and T1b. Similarly, the capacitance components C₃ are produced between the via connections V which are at different potentials.

This structure allows a significant reduction in the parasitic capacitance between the capacitance structure K and the substrate.

A further exemplary embodiment is shown in FIG. 2. The capacitance structure K corresponds essentially to that shown in FIG. 1. One difference is that the third substructure T1c is constructed merely from the latticed region G1c. This admittedly means that the useful capacitance does not have the capacitance components C₁ in the metallization plane M3 or the capacitance components between the via connections V which are at different potentials between the substructure T1b and the substructure T1c. However, omitting the metal plates P1c significantly reduces the parasitic capacitance.

A further exemplary embodiment is shown in FIG. 3. The capacitance structure K corresponds essentially to that in FIG. 1. One difference in this example is that the substructure T1c is in the form of a single-piece metal plate MP which is connected by means of via connections V to the metal plates P1b of the substructure T1b and is thus electrically connected to the first connecting line.

The further capacitance structure K of a semiconductor component based on the invention is shown in FIG. 4. This capacitance structure K corresponds to that in FIG. 1. In this exemplary embodiment, the metal plates P1a, P1b and P1c have been replaced by electrically conductive node points KNa to KNc, which are produced between via connections V in the exemplary embodiment. If the capacitance structure K comprises, by way of example, merely the substructures T1c—latticed region G1c and node points KNc—and the substructure T1b—latticed region G1b and node points KNb—then the node points KNb and KNc are respectively in the form of end points of a via connection V.

Provision may also be made for the capacitance structure K to be constructed from the two substructures T1b and T1c—the design of both corresponds to that of a first substructure—and for the via connections V extending upward from the node points KNb in the positive z direction to make contact with a region of the semiconductor component which is no longer part of the capacitance structure K.

The capacitance components C₁, C₂ and C₃ (not shown) contributing to the useful capacitance of the capacitance structure K are produced essentially in line with those in the capacitance structure shown in FIG. 1.

FIG. 5 shows a plan view of a substructure such as is implemented in the substructure T1a, for example. The latticed region G1a has square cutouts which respectively contain a centrally arranged square metal plate P1a. The capacitance components C₁ are formed between each of the opposing surface regions.

FIG. 6 shows a further plan view of a substructure. In this example, a latticed region, for example G1a, is in a form such that it has circular cutouts which respectively contain a round metal plate, for example P1a.

In all of the exemplary embodiments, the substructure T1c is closest to the semiconductor substrate.

The exemplary embodiments are each shown and explained with three metallization planes M1 to M3. Provision may also be made for just one, two or more than three metallization planes to be produced which have a respective substructure produced in them, each metallization plane having the same substructure or a respective different substructure produced in it.

1. A semiconductor component comprising a semiconductor substrate having an insulating layer on the semiconductor substrate and having a capacitance structure in the insulating layer,
wherein the capacitance structure comprises a first substructure which has a first cohesive latticed metal region which extends in a first common plane parallel to the substrate surface such that it has common top and bottom surfaces which limit the first cohesive latticed metal region in each of its subregions from above and from below, wherein the first cohesive latticed metal region is electrically connected to a first connecting line; and a first substructure having electrically conductive regions arranged in cutouts in the first cohesive latticed metal region of the first substructure at a distance from edge regions of the cutouts in the common plane, wherein the electrically conductive regions are electrically connected to a second connecting line, and
wherein the electrically conductive regions comprise one of metal plates or node points between via connections.

2. The semiconductor component as claimed in claim 1, wherein the capacitance structure further comprises a second substructure parallel to and at a distance from the first substructure wherein the second substructure comprises a second cohesive latticed metal region which extends in a second common plane parallel to the substrate surface such that it has common top and bottom surfaces which limit the second latticed metal region in each of its subregions from above and below, and wherein the first and second substructures are electrically connected.

3. The semiconductor component as claimed in claim 2, wherein the second substructure is of the same design as the first substructure, and the first and second substructures are arranged offset from one another such that the electrically conductive regions of the first substructure are arranged vertically above crossing points in the second cohesive latticed metal region of the second substructure, and crossing points in the first cohesive latticed metal region of the first substructure are arranged vertically above electrically conductive regions of the second substructure.

4. The semiconductor component as claimed in claim 3, wherein the crossing points in the first cohesive latticed metal region of the first substructure are electrically connected to the electrically conductive regions of the second substructure, and the electrically conductive regions of the first substructure are electrically connected to the crossing points in the second cohesive latticed metal region of the second substructure, by means of at least one respective via connection.

5. The semiconductor component as claimed in claim 2, wherein the second cohesive latticed metal region of the second substructure is offset from the first substructure, so that the electrically conductive regions of the first substructure are arranged vertically above the crossing points in the second cohesive latticed metal region of the second substructure.

6. The semiconductor component as claimed in claim 5, wherein the electrically conductive regions of the first substructure and the crossing points in the second cohesive latticed metal region of the second substructure are electrically connected by means of one or more respective via connections.

7. The semiconductor component as claimed in claim 2 further comprising a metal plate electrically connected to one of the crossing points in a latticed region of the first and second substructure or to electrically conductive regions of the first and second substructures by means of one of more respective via connections.

8. The semiconductor component as claimed in claim 1, wherein the first cohesive latticed metal region has at least two square or round cutouts.
